(19) United States
(12) Patent Application Publication
(10) Pub. No.: US 2006/0234138 A1
(43) Pub. Date: Oct. 19, 2006

(54) Hard mask arrangement

(76) Inventors: Rodger Fehlhaber, Munchen (DE); Helmut Tews, Munchen (DE)

Correspondence Address: BRINKS HOFER GILSON & LIONE;INFINEON, PO BOX 10395, CHICAGO, IL, 60610, US

(21) Appl. No.: 11/393,017

(22) Filed: Mar. 30, 2006

Related U.S. Application Data
(63) Continuation of application No. PCT/DE04/02185, filed on Sep. 30, 2004.

(30) Foreign Application Priority Data
Sep. 30, 2003 (DE) 103 45 455.1

(51) Int. Cl. G03F 1/00; H01L 21/311

(52) U.S. Cl. 430/5; 430/4; 438/694

(57) ABSTRACT

An interconnect connection structure having first and second interconnects and multiple connection elements that electrically connect the first interconnect to the second interconnect is described. The multiple connection elements are formed laterally in a lateral region of the first and second interconnects relative to an overlay orientation of the interconnects. A central region may be free of connection elements so that electro-migration properties of the connection structure are improved and the current-carrying capacity is increased.

### PRIORITY AND CROSS REFERENCE TO RELATED APPLICATION

This application is a continuation of International Application No. PCT/DE2004/002185, filed Sep. 30, 2004, which claims priority to German application 103 45 455.1, filed Sep. 30, 2003, both of which are incorporated in their entirety by reference herein.

### BACKGROUND OF THE INVENTION

1. Field of the Invention

The invention relates hard masks, and particularly to methods for producing a hard mask and hard mask arrangements.

2. Description of the Related Art

Optical lithography is used to produce feature sizes that are smaller than 100 nm. The chemistry used for a photoresist material, the production of mask(s) used in the optical lithography techniques and the complexity of the lithography tool used may be cost-intensive at these reduced feature sizes. The production of feature sizes smaller than 100 nm (“sub-100 nm structures”) has led to the development of optical lithography methods using light having the wavelength λ=193 nm, and even to the development of optical lithography techniques using light having the wavelength λ=157 nm, also referred to as a “65 nm” technology node.

Optical lithography techniques using light with a wavelength=157 nm use new photoresist material(s) having technical requirements. Such materials have not heretobefore been developed, despite considerable development efforts. In the context of optical lithography using light having the wavelength λ=157 nm, new materials and new methods for the production of masks used in the lithography method may be used. The development of such materials and methods may be in turn very costly. A new and expensive infrastructure may be required for the production of masks for 157 nm lithography methods. For example, such techniques may use new inspection tools and new repair tools. Finally, the tool, that is to say the apparatus which carries out the lithography method using light having the wavelength λ=157 nm, is itself expensive and requires considerable development work.

Resolution enhancement techniques (“RET”) are used to produce structures having the corresponding desired size in the most critical—in terms of resolution—layers of a wafer of the 65 nm technology node, and to thus improve a customary 193 nm lithography. In particular, for the production of very small gate structures with precise control of the critical dimension (“CD”), the only suitable approach at the present time is to be seen in the use of alternating phase shift masks (“altPSM”), in association with double exposure. However, the double exposure and the alternating phase shift masks dramatically increase the process costs.

Atomic layer epitaxy techniques, also referred to as atomic layer deposition methods (ALD methods), are used to deposit silicon dioxide and aluminum oxide. Other techniques may apply a silicon oxide to a photoresist structure using a plasma CVD method. The silicon layer is subsequently partly removed, and the upper region of the photoresist structure is uncovered. The photoresist structure is then removed. However, the reliability may be very low since, on account of the process conditions present in the context of the plasma CVD method, the photoresist structure is destroyed or thermally treated in such a way that it can subsequently be removed only with great difficulty and with possible impairment of the rest of the circuit structure formed.

In order to reduce the pitch for forming a hard mask, spacer structures may be produced from a layer formed by conformal turn-off. The structures extending over the substrate and adjoining the spacers are removed after spacer formation has been effected. In other techniques, two hard mask layers are deposited so that one layer lies above another, and a photoresist layer is applied above the second hard mask layer. Firstly, a region of the second hard mask layer that is uncovered by means of the patterned photoresist is removed in such a way that the portions of the second hard mask layer which remain beneath the photoresist layer is subsequently used as an etching mask for etching the first hard mask layer. The second hard mask layer is trimmed and the uncovered regions of the first hard mask layer are subsequently etched using the remaining material of the second hard mask layer as a hard mask. The patterned first hard mask layer is subsequently trimmed in turn.

Therefore, there is a need for a cost-effective sublithographic hard mask and production process.

### SUMMARY OF THE INVENTION

The present invention produces a sublithographic hard mask using a cost-effective production process. In a method for the production of a hard mask, a photoresist layer is applied on a substrate. The applied photoresist layer is subsequently patterned and a hard mask layer is applied to the patterned photoresist layer by means of an atomic layer epitaxy method. A portion of the hard mask layer is subsequently removed with a corresponding portion of the pattern photoresist layer being uncovered. To put it another way, the portion of the hard mask layer is removed, so that a corresponding portion of the patterned photoresist layer is uncovered. The uncovered patterned photoresist layer is subsequently removed.

A hard mask arrangement may have a substrate and also a patterned photoresist layer applied on the substrate. A hard mask layer is applied on the patterned photoresist layer.

### DESCRIPTION OF THE DRAWINGS

Exemplary embodiments of the invention are explained below with reference to the accompanying drawings. Identical, functionally identical, or similar elements and signals are referred to with the same reference symbols in the figures unless stated otherwise.

FIG. 1 shows a hard mask arrangement in accordance with a first exemplary embodiment of the invention at a first point in time during its production.

FIG. 2 shows a hard mask arrangement in accordance with the first exemplary embodiment of the invention at a second point in time during its production.

FIG. 3 shows a hard mask arrangement in accordance with the first exemplary embodiment of the invention at a third point in time during its production.

FIG. 4 shows a hard mask arrangement in accordance with the first exemplary embodiment of the invention at a fourth point in time during its production.

FIG. 5 shows a hard mask arrangement in accordance with the second exemplary embodiment of the invention at a first point in time during its production.

FIG. 6 shows a hard mask arrangement in accordance with the second exemplary embodiment of the invention at a second point in time during its production.

FIG. 7 shows a hard mask arrangement in accordance with the second exemplary embodiment of the invention at a third point in time during its production.

### DESCRIPTION OF THE PREFERRED EMBODIMENTS

The invention may involve an application of a hard mask layer directly to the patterned photoresist layer using a low-temperature atomic layer epitaxy method. Horizontal regions of the hard mask layer are subsequently etched by an anisotropic etching process or technique. The hard mask layer may be considered “opened”, so that the patterned photoresist layer is at least partly uncovered in order subsequently to be removed. The vertical portions of the hard mask layer that have not been removed remain and have a layer thickness that can be set very precisely according to the dimensioning desired in the context of the atomic layer epitaxy method.

The present invention provides a cost-effective production process for forming sublithographic structures in a hard mask using customary mask types. On account of the use of an atomic layer epitaxy method for forming the hard mask layer, the thickness of the hard mask layer may be precisely controlled, and the hard mask layer is applied to the patterned photoresist layer perfectly conformally, so that the hard mask is formed accurately to one atomic layer, whereby the hard mask produced is reliable even in terms of the critical dimension (“CD”).

The hard mask layer may be applied directly on the patterned photoresist layer by the use of an atomic layer epitaxy method, since the atomic layer epitaxy method is performed at a temperature of approximately 100° C., (i.e., at a temperature that is considerably below the baking temperature of a customary photoresist material). The photoresist material used may be any desired photoresist material, also referred to as photoresist.

The hard mask layer is formed from a dielectric, preferably from silicon dioxide (SiO₂) or aluminum oxide (Al₂O₃). Alternatively or in addition, the hard mask layer may be formed from a suitable dielectric material, such as zirconium oxide (ZrO₂), hafnium oxide (HfO₂), an oxide of a rare earth material, or an oxide of a lanthanide. In general, it is thus possible to use any suitable dielectric material for forming the hard mask layer, preferably any suitable dielectric material that can be applied by means of an atomic layer epitaxy method. A sublithographic hard mask structure may also be formed using conventional lithography masks. In particular, as will be explained in more detail below, two or three of the following lithographic elements are used to form the sublithographic hard mask:

1) a medium-resolution photoresist mask to define the structures;
2) a medium-resolution mask to select larger regions to be exposed; and
3) a medium-resolution trimming mask.

The three medium-resolution masks allow production of (i.e., fabrication of) the sublithographic hard mask structures according to the invention, such as by providing a basis for subsequently carrying out a gate etch. The process flow according to the invention thus replaces the complex and cost-intensive resolution enhancement techniques and mask schemes, for example the use of alternating phase shift masks, by a simple and cost-effective new process sequence. The hard mask layer is formed from a dielectric material, such as a silicon dioxide or aluminum oxide, or any of the materials described above.

Prior to the removal of the patterned photoresist layer, the portion of the hard mask layer is removed preferably by means of an anisotropic etching method, particularly preferably by an anisotropic dry etching method, such as a reactive ion etching method (“RIE”). The material of the photoresist layer that covers the photoresist material, (i.e., the “cover portion” of the hard mask layer that is arranged above the photoresist layer) is removed, where at least a portion of the photoresist layer, such as the entire photoresist layer, is uncovered. A parallelepiped—open, (i.e., not provided with hard mask material) on the top side—made of photoresist with spacers made of the hard mask material is formed.

After the patterned photoresist layer has been removed, a second portion of the hard mask layer may be removed, such as by using a medium-resolution trimming mask, where the desired hard mask may be formed in the form of ridge structures by using a clipping or etching away of the still undesired portions of the hard mask layer. The hollow parallelepiped structure may already be used, if appropriate, as a sublithographic hard mask if this structure suffices to carry out the subsequent etch of the substrate that is desired by means of the hard mask.

Multiple electronic circuits may be integrated in the substrate. The hard mask serves in particular for subsequently etching a gate stack arranged beneath the hard mask. Furthermore, after the deposition of the first hard mask layer, a second hard mask layer made of a different material may be applied to the patterned photoresist layer, the second hard mask layer preferably in turn being applied by an atomic layer epitaxy method. This allows simultaneous production of complex structures made of hard mask material having different thicknesses. Particularly preferably, the first hard mask layer may be formed from aluminum oxide and the second hard mask layer is formed from silicon dioxide, or vice versa. Other materials are likewise taken into consideration as hard mask layers if they can be conformally deposited at a low temperature, and if they can subsequently be etched selectively with respect to one another. In particular, the above-described materials of the hard mask layer can be used if the materials used for the hard mask layer and the second hard mask layer can be etched selectively with respect to one another.

The use of two different hard mask layer materials for the first hard mask layer and the second hard mask layer is an example of a simple and cost-effective selective etching of the second hard mask layer without the first hard mask layer being attacked. Preferably, a second photoresist layer made of customary photoresist is applied to the second hard mask layer and the second photoresist layer is patterned, by means of a medium-resolution mask in accordance with this exemplary embodiment of the invention. After the removal of the developed region, that is to say of the illuminated region of the photoresist layer (in the case of a positive lithography method), or of the non-developed region, (i.e., of the un-illuminated region of the second photoresist layer in the case of a negative lithography method), a structurally enlarged region may be formed to serve as a landing pad, (i.e., clearly as a terminal region for making contact with a terminal of an electronic component in the substrate), for example as a landing pad for an electrical contact in an inverter circuit.

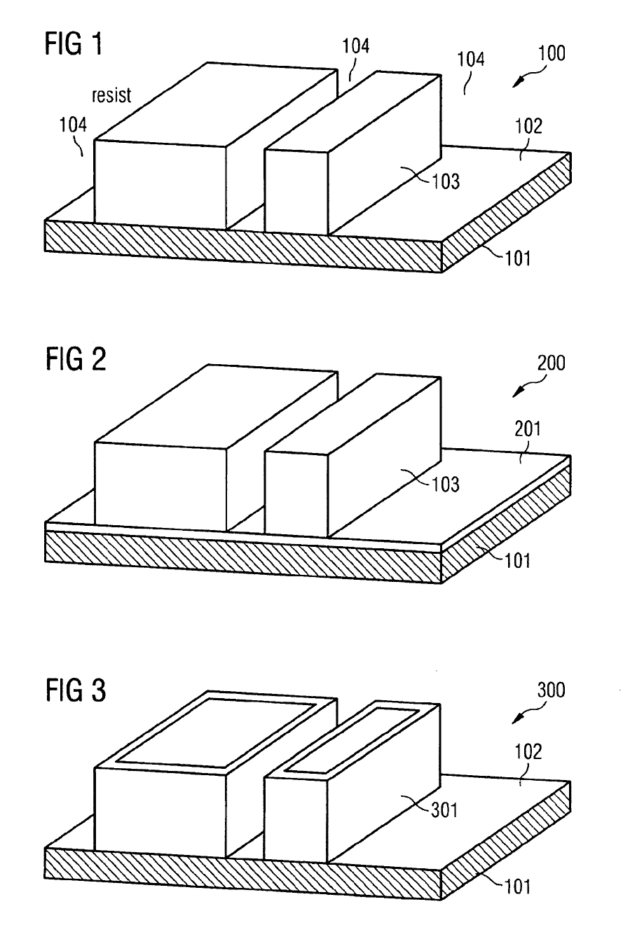

FIG. 1 shows a hard mask arrangement 100 in accordance with a first exemplary embodiment of the invention at a first point in time during its production. The hard mask arrangement 100 has a wafer substrate 101 made of silicon or some other semiconductor material, into which multiple electronic circuit elements or electronic switching circuits are integrated, for example electrical resistors, capacitors, inductors, complementary metal oxide semiconductor (CMOS) transistors, field effect transistors (FETs), metal oxide semiconductor field effect transistors (MOSFET's), bipolar transistors (BPT's), and the like.

A photoresist layer 103 is applied on the upper surface 102 of the substrate 101 a spin-on method. The structures to be formed in the photoresist layer 103 are defined using a medium-resolution photoresist mask (not shown). After the exposure of the regions of the photoresist layer 103 that are to be removed (a positive lithography method is used in accordance with this exemplary embodiment), the photoresist layer 103 is patterned, such that the exposed, and thus developed regions, of the photoresist layer 103 are removed by a wet etching method. Openings 104 and/or trenches in the photoresist layer 103 are formed, so that the upper surface 102 of the substrate 101 is partly uncovered. After patterning has been affected, the patterned photoresist layer 103 is baked by means of heat treatment at a temperature of between 100° C. and 200° C.

Subsequently, as is shown in FIG. 2 in the case of the hard mask arrangement 200 at a second point in time during its production, a hard mask layer 201 made of aluminum oxide is applied. The hard mask layer 201 may be an atomic layer epitaxy layer. The hard mask layer 201 may be applied by an atomic layer epitaxy method, to the photoresist layer 103 and the uncovered upper surface 102 of the substrate 101, so that the entire surface of the patterned photoresist layer 103 and also the uncovered regions of the upper surface 102 of the substrate are covered completely conformally with the hard mask layer 201 made of aluminum oxide (Al₂O₃). In the upper regions (i.e., directly below the upper surface 102 of the substrate 101), gate stack structures are formed (not shown), which may be etched using the hard mask produced as described herein. The thickness of the photoresist layer 103 may be chosen to be relatively small (i.e., in a range of, for example, between 60 nm and 200 nm) since the photoresist layer 103 is not used as an etching mask. A method for ALD deposition of aluminum oxide is used in accordance with the exemplary embodiment of the invention. The atomic layer epitaxy method is carried out at a process temperature in a range from around 50° C. to around 100° C. The thickness of the hard mask layer 201 is dependent on a targeted final lateral dimension, such as a lateral feature size of the hard mask to be produced. The thickness of the hard mask layer 201 may be set accurately to one atomic layer. In an exemplary embodiment, the hard mask layer 201 has a thickness in a range from around 10 nm to around 50 nm.

As is illustrated in FIG. 3 for a hard mask arrangement 300 at a third point in time during its production, a portion of the hard mask layer 201 may be removed using an anisotropic dry etching technique using a reactive ion etching (“RIE”). The regions above the substrate 101 that are also not covered by the patterned photoresist layer 103 are removed, so that the uncovered regions of the upper surface 102 of the substrate 101 as illustrated in FIG. 1 are uncovered anew. Furthermore, using the anisotropic dry etching techniques, material of the hard mask layer is removed so that the upper surface of the patterned photoresist layer 103 is uncovered.

Cavity parallelepipeds 301 open at the top, which are initially still filled with the material of the patterned photoresist layer 103, clearly arise. The photoresist is subsequently stripped, (i.e., removed), for example by incinerating the photoresist material of the patterned photoresist layer 103. In accordance with the exemplary embodiment of the invention, the height of the cavity parallelepipeds 301 is approximately 50 nm. The width of the edge structures of the hollow parallelepipeds 301 produced is substantially the same as the layer thickness of the hard mask layer 201; in accordance with this exemplary embodiment, the hard mask layer 201 thus has a thickness of between 10 nm and 50 nm.

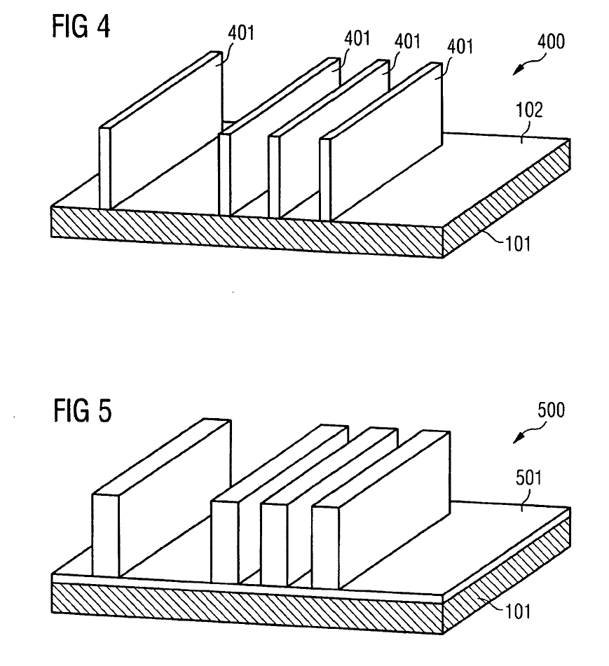

FIG. 4 illustrates the hard mask arrangement 400 at a fourth point in time during its production. As shown in FIG. 4, using a medium-resolution trimming mask, the region of the remaining first hard mask layer, (i.e., the hollow parallelepipeds 301) is removed in a subsequent step, so that ridges 401 are produced having the height of 50 nm and the width of 10 nm. The ridges 401 produced form the desired hard mask for etching the gate structures situated beneath the ridges 401.

FIG. 5 shows a second exemplary embodiment of a hard mask arrangement 500 at a first point in time during its production. The second exemplary embodiment proceeds from a structure that has a first sublithographic hard mask, such as that produced as in accordance with the method of the first exemplary embodiment. In this case, the hard mask arrangement 400 illustrated in FIG. 4 is taken as a basis for the method—illustrated below—for the production of the hard mask arrangement in accordance with the second exemplary embodiment of the invention.

Only two medium-resolution masks are used in accordance with the first exemplary embodiment of the invention, whereas three medium-resolution masks are used in accordance with the second exemplary embodiment. The second exemplary embodiment of the invention makes produces two different thicknesses of the hard masks to be formed. The hard mask having two different thicknesses may be used for the production of a thin hard mask, such as a thin sublithographic hard mask for ultrashort gate structures plus a second mask region for etching longer gate structures or for the production of landing pads (i.e., larger terminal regions for making contact with the electronic components in the substrate 101) for making contact with an inverter terminal of an inverter circuit which is integrated into the substrate 101. After the hard mask 401 has been produced as shown in FIG. 4, such as after the hard mask layer has been trimmed, a second dielectric layer is conformally deposited, using an atomic layer epitaxy technique, on the entire surface of the hard mask 401 and also the uncovered regions of the upper surface 102 of the substrate 101. The second hard mask layer 501 may be a silicon dioxide (SiO₂) and have a thickness of approximately 20 nm.

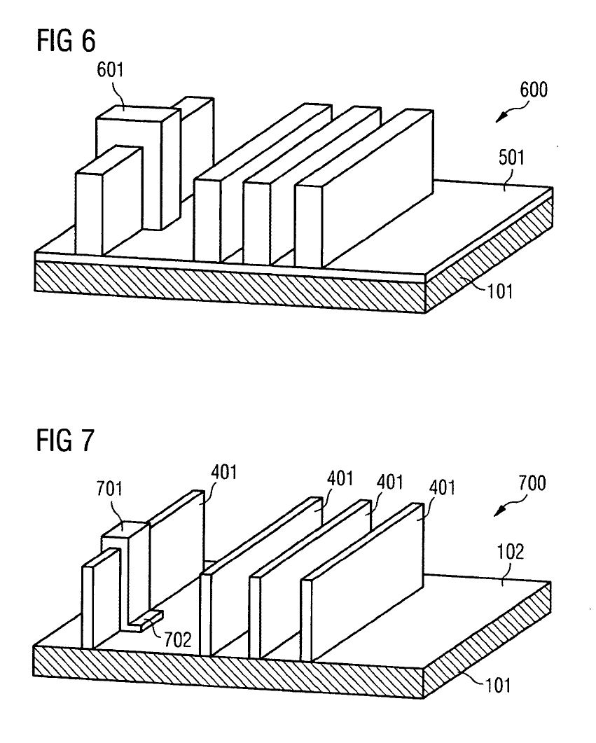

A second photoresist layer 601 (cf. hard mask arrangement 600 at a second point in time during its production in FIG. 6) is applied on the second dielectric layer (i.e., on the second hard mask layer 501). With an optical lithography technique, using a medium-resolution mask, the region(s) is defined are defined having a thicker dielectric layer, such as a layer that results from the first hard mask layer and the second hard mask layer, and is exposed and thus developed. Using a suitable etching technique, the exposed regions of the second photoresist layer 601 are removed so that a patterned second photoresist layer is formed. Afterward, using a wet etching technique that selectively etched the material of the second hard mask layer 501 with respect to the material of the first hard mask layer, the region not situated under the second photoresist layer 601 (i.e., the uncovered region of the second hard mask layer 501) is removed (cf. hard mask arrangement 700 in accordance with the second exemplary embodiment of the invention at a third point in time of the method for its production in FIG. 7). The uncovered regions of the second hard mask layer 501 are removed by the selective wet etching method used, so that a patterned second hard mask layer 701 is formed. Afterward, the patterned second photoresist layer 601 is removed by incineration and the hard mask arrangement 700 is thus formed, which has on the one hand the thin ridges 401 of the hard mask having the width of 10 nm, and also widened regions formed by the second hard mask 701.

The region 702—situated laterally below the second photoresist layer 601—of the second hard mask layer 701 that remains after etching has been effected may be removed by a suitable anisotropic etching method such as using an RIE technique. Using the hard mask arrangement 700 formed in FIG. 7, desired structures are then etched. For example, a landing pad below the remaining second hard mask layer 701 or the gate stacks below the ridges 401 having the first gate length may be etched. By the patterned second hard mask layer 701, gate stacks may be produce having a second gate length that is greater than the first gate length.

The first hard mask layer may have a thickness of approximately 10 nm and the second hard mask layer has a thickness of approximately 20 nm. With the hard mask arrangement 700, the ridges 401, and the patterned second hard mask layer 701, structures having a gate length of 10 nm and structures having a gate length of 50 nm may be produced. Although sublithographic hard mask structures have been produced without carrying out a gate trimming, no cost-intensive lithography techniques such as, for example, alternating phase shift masks are required according to the invention.

Alternatively or in addition, the method in accordance with the second exemplary embodiment is begun with a hard mask arrangement shown in FIG. 2. The second hard mask layer is applied directly to the as yet non-patterned first hard mask layer, and the subsequent patterning steps are applied to both hard mask layers in a corresponding manner illustrated above in the context of the two exemplary embodiments, so that a hard mask having two different thicknesses is also formed.

1. A method for the production of a hard mask, comprising
applying a photoresist layer on a substrate;
patterning the photoresist layer;
applying a hard mask layer to the patterned photoresist layer using an atomic layer epitaxy technique;
removing a portion of the hard mask layer, a corresponding portion of the patterned photoresist layer being uncovered; and
removing the uncovered patterned photoresist layer.

2. The method of claim 1, where the hard mask layer comprises silicon dioxide.

3. The method of claim 1, where the hard mask layer comprises aluminum oxide.

4. The method of claim 1, comprising removing the portion of the hard mask layer using an anisotropic etching technique.

5. The method of claim 4, comprising removing the portion of the hard mask layer using an anisotropic dry etching technique.

6. The method of claim 4, comprising removing the portion of the hard mask layer using a reactive ion etching technique.

7. The method of claim 1, comprising removing a second portion of the hard mask layer after removal of the patterned photoresist layer.

8. The method of claim 7, where removing the second portion of the hard mask layer comprises trimming a hard mask layer remaining after the removal of the patterned photoresist layer.

9. The method of claim 1, comprising applying a second hard mask layer to the hard mask layer after the removal of the patterned photoresist layer.

10. The method of claim 9, where the hard mask layer comprises aluminum oxide.

11. The method of claim 10, comprising forming the second hard mask layer from silicon dioxide.

12. The method of claim 11, where the hard mask layer is formed from one of zirconium oxide, hafnium oxide, an oxide of a rare earth material, or an oxide of a lanthanide.

13. The method of claim 11, where the second hard mask layer is formed from one of zirconium oxide, hafnium oxide, an oxide of a rare earth material, or an oxide of a lanthanide.

14. The method of claim 9, comprising applying the second hard mask layer with an atomic layer epitaxy method.

15. The method of claim 14, where the hard mask layer comprises aluminum oxide.

16. The method of claim 15, comprising forming the second hard mask layer from silicon dioxide.

17. The method of claim 16, where the hard mask layer is formed from one of zirconium oxide, hafnium oxide, an oxide of a rare earth material, or an oxide of a lanthanide.

18. The method of claim 16, where the second hard mask layer is formed from one of zirconium oxide, hafnium oxide, an oxide of a rare earth material, or an oxide of a lanthanide.

19. The method of claim 9, comprising:
applying a second photoresist layer to the second hard mask layer, and
patterning the second photoresist layer.

20. A hard mask arrangement, comprising:
a substrate;
a patterned photoresist layer applied on the substrate; and
a hard mask layer applied on the photoresist layer, a portion of the hard mask being removed to expose a corresponding portion of the patterned photoresist layer,
where the exposed patterned photoresist layer is configured to be removed.

21. The hard mask of claim 20, where the hard mask layer comprises silicon dioxide or aluminum oxide.

22. The hard mask of claim 20, comprising a second hard mask layer applied to the hard mask layer, the second hard mask being applied to the patterned photoresist after the patterned photoresist layer is removed.

23. The method of claim 22, where the hard mask layer is formed from one of aluminum oxide, zirconium oxide, hafnium oxide, an oxide of a rare earth material, or an oxide of a lanthanide.

24. The method of claim 22, where the second hard mask layer comprises one of silicon dioxide, zirconium oxide, hafnium oxide, an oxide of a rare earth material, or an oxide of a lanthanide.

25. A hard mask, comprising
an atomic-layer-epitaxy applied hard mask layer being to a patterned photoresist layer on a substrate, at least a portion of the atomic-layer-epitaxy applied hard mask layer being removed exposing at least a portion of the patterned photoresist layer.

26. The hard mask of claim 25, where a portion of the photo resist layer is being exposed is removed from the substrate.

27. The hard mask of claim 26, where the hard mask layer comprises silicon dioxide or aluminum oxide.

28. The hard mask of claim 1, comprising a second hard mask layer applied to the hard mask layer after the removal of the patterned photoresist layer.
